(19) United States
(12) Patent Application Publication
(10) Pub. No.: US 2026/0367141 A1
(43) Pub. Date: Nov. 19, 2026

(54) TESTING APPARATUS FOR SEMICONDUCTORS, CORRESPONDING SHUTTLE DEVICE, USE THEREOF AND METHOD

(71) Applicant: STMicroelectronics International N.V., Geneva (CH)

(72) Inventors: Stefano MARTIGNONI, Vaprio D'Adda (IT); Fabio AQUILINI, Lomagna (IT); Fabio GALIMBERTI, Carate Brianza (IT)

(73) Assignee: STMicroelectronics International N.V., Geneva (CH)

(21) Appl. No.: 19/674,280

(22) Filed: May 12, 2026

(30) Foreign Application Priority Data
May 14, 2025 (IT) 102025000010808

(51) Int. Cl. G01R 31/28

(52) U.S. Cl. CPC G01R 31/2867; G01R 31/2862; G01R 31/2875; G01R 31/2881

(57) ABSTRACT

A loading station receives, optionally as unpackaged semiconductor dice, arrays of semiconductor dice under test. Test stations are configured to perform respective tests by applying under controlled environmental conditions respective individual electrical stimulation signals to semiconductor dice under test and collecting therefrom respective individual reaction signals in response to the respective individual electrical stimulation signals being applied thereto. Each test station identifies as defective individual semiconductor dice under test that fail to pass one or more respective tests in a test station. A robotized conveyance structure advances the arrays of semiconductor dice under test in a test path through the test stations towards an unloading station where individual semiconductor dice found to be defective are directed to a reject destination.

### PRIORITY CLAIM

This application claims the priority benefit of Italian Application for Patent No. 102025000010808 filed on May 14, 2025, the content of which is hereby incorporated by reference in its entirety to the maximum extent allowable by law.

### TECHNICAL FIELD

The description relates to applying stress to semiconductor devices under test.

Solutions as described herein can be applied, for instance, to applying electrical and/or thermal stress to integrated circuit (IC) semiconductor devices under test.

Solutions as described herein can be applied, for instance, to burn-in testing of integrated circuit semiconductor devices with the purpose of facilitating both static and dynamic testing before packaging (after wafer sawing, for instance).

### BACKGROUND

Burn-in testing (a stress test that typically employs voltage and/or temperature to accelerate the insurgence of latent reliability defects in a semiconductor device) is currently adopted in the field of testing, for high-power devices, for instance.

Burn-in testing aims at eliminating potential failure likely to occur in the early phases of the lifetime of a semiconductor product (so-called Infant Mortality Failure).

The observed failure rate curve may typically exhibit a “bathtub” shape over time with a failure rate that: is higher in the early phases of the product lifetime (exposed to Infant Mortality Failure); decreases over a mid-term span of the product lifetime to a nearly constant value determined essentially by random failures; and increases again towards the end of the product lifetime to a higher value determined essentially by Wear Out Failures.

Burn-in testing can be performed either at wafer level and/or at package level (after die packaging, for instance).

Wafer level testing turns out to be critical for certain types of tests: for instance, in order to maintain good contact, a high pressure (about 5 bar) is required to be applied with a high degree of accuracy to the wafer, which could break during testing.

Package-level testing involves increased costs (associated to performing package operations for dice that are then discarded).

It may also lead to reliability issues in so far as, especially in case of systems in a package, the test may not reveal defective dice (other dice may compensate at the early stage) so that the defect may become evident only during the operational life of the device.

There is a need in the art to contribute in providing improved solutions in the context referred to in the foregoing.

This applies primarily to the possibility of overcoming the disadvantages of conventional wafer level testing and package-level testing as discussed in the foregoing.

### SUMMARY

Solutions as described herein relate to a testing apparatus.

Solutions as described herein can take advantage of a type of shuttle device (hereinafter referred to as “sandwich”) to convey semiconductor devices (dice) under test in such apparatus.

Solutions as described herein can also relate to a possible use of such a device and/or to a corresponding method for (die-level) testing of semiconductor dice.

The testing apparatus described herein may be supplied to an end user – a manufacturer of semiconductor devices, for instance – equipped with a conveyance structure of the semiconductor dice under test that does not necessarily include shuttle devices as described herein.

Consequently, such shuttle devices may be either supplied originally together with the apparatus or represent by themselves a distinct form of supply to advantageously equip a testing apparatus in order to facilitate performing testing of semiconductor dice as described herein.

According to solutions as described herein, burn-in testing can be performed at die level (on “bare” dice, namely after wafer sawing but before packaging operations) creating a die carrier able to handle both static and dynamic tests during a same test operation.

Static testing facilitated by solutions as described herein include High Temperature Gate Bias (HTGB), High Temperature Reverse Bias (HTRB) and Body Diode Stress (BDS).

Dynamic testing facilitated by solutions as described herein include Dynamic Reverse Bias (DRB) and Dynamic Gate Stress (DGS).

In solutions as described herein, a die carrier may be provided including a chamber suited to have applied an inert gas (nitrogen, for instance). This facilitates, on the one side, pressurization of the chamber to withstand high-voltage and, on the other side, cooling of the dice to withstand high-currents: in fact, during testing dice may exhibit a marked power dissipation.

In solutions as described herein, a plurality of power (integrated circuit, IC) semiconductor devices can be formed in a wafer, which then undergoes dicing (sawing) to form individual dice, each having at least one power semiconductor device formed thereon after which burn-in operations are performed on the dice that are then packaged.

In solutions as described herein, burn-in operations include applying to the dice a voltage of at least 1000V, optionally at least 1200V, and a current of at least 8A, optionally at least 10A, subjecting the dice to an inert gas flux.

Testing apparatus for (power) semiconductor devices according to solutions as described may be configured to operate on devices under test that are conveyed through plural test stations via shuttle devices comprising: a die carrier having a plurality of cavities (slots) for holding a plurality of dice, each having at least one power semiconductor device formed thereon; a probe tip substrate having, on a first surface, an array of contact tips configured to contact the dice and, on a second, opposed surface, an array of contact terminals configured to apply to the dice a respective voltage of, for instance, at least 1200V (but, for instance, below 2500V) and a respective current of at least 10A (but, for instance below 14A); a cover member including a plurality of pressure formations (so-called pogo-pins, for instance) configured to apply to the dice respective pressure forces to hold the dice in contact with the contact tips of the probe tip substrate; and a gas passageway between the die carrier and the cover member configured to facilitate flow of an inert gas to provide pressurization and cooling.

Advantageously, solutions as disclosed herein facilitate burn-in operations that: include both static tests such as High Temperature Gate Bias (HTGB), High Temperature Reverse Bias (HTRB) and Body Diode Stress (BDS) and dynamics tests such as Dynamic Reverse Bias (DRB) and Dynamic Gate Stress (DGS); and/or involve subjecting the devices under test to temperatures above 120° C., optionally above 150° C. (below 200° C., for instance).

Advantageously, solutions as disclosed herein are suited to operate on arrays of individual semiconductor dice under test obtained by sawing semiconductor dice wafers.

Advantageously, solutions as disclosed herein operate on individual semiconductor dice under test that comprise unpackaged semiconductor dice, namely semiconductor dice before (or exempt from) a packaging operation.

### BRIEF DESCRIPTION OF THE DRAWINGS

One or more embodiments will now be described, by way of example only, with reference to the annexed figures, wherein:

FIG. 1 is a flow-chart that illustrates a possible sequence of steps in an exemplary method;

FIG. 2 is an exploded perspective view of a device (“sandwich”) suited to be used in solutions as described herein;

FIG. 3 is a diagram illustrative of a possible functional arrangement of stages/cells in apparatus (equipment) as described herein;

FIGS. 4-9 are schematically illustrative of steps in a process as exemplified in the flow-chart of FIG. 1 that can be performed using a device exemplified in FIG. 2 in apparatus as exemplified in FIG. 3;

FIG. 10 is a plan view of a possible implementation of an apparatus according to solutions described herein;

FIG. 11 is exemplary of a way of configuring apparatus 1000 as illustrated in FIGS. 3 and 10;

FIGS. 12, 13A, 13B, and 14 illustrate more in detail an advantageous way of implementing a of a device (“sandwich”) as illustrated in FIG. 2; and

FIGS. 15-19 are illustrative of various exemplary tests that can be carried out using apparatus as described herein.

### DETAILED DESCRIPTION

The figures are drawn to clearly illustrate relevant aspects of the solutions described herein and are not necessarily drawn to scale. The edges of features drawn in the figures do not necessarily indicate the termination of the extent of the feature.

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular configurations, structures, or characteristics may be combined in any adequate way in one or more embodiments.

The headings/references used herein are provided merely for convenience and hence do not define the extent of protection or the scope of the embodiments.

Unless the context indicates otherwise, like parts or elements are indicated throughout the figures annexed herein with like references/numerals and a corresponding description will not be repeated for the sake of brevity.

For the sake of simplicity and ease of explanation, a same designation may be applied throughout this description to designate: a node or line as well as a signal occurring at that node or line; a component (such as a capacitor, resistor or inductor of coil) as well as electrical parameters (capacitance, resistance, inductance) thereof.

Also, when it is mentioned that an element is “connected to” or “coupled to” another element, it should be understood that an element may be coupled directly to another element or that still another element may be interposed therebetween.

On the contrary, when it is possibly mentioned that an element is “connected directly to” or “coupled directly to” another element, it should be understood that still another element is not interposed therebetween.

Solutions as described herein can be applied, for instance, to burn-in testing of (integrated circuit, IC) semiconductor devices for use in the automotive, industrial, and power discrete electronics sectors.

P-channel metal-oxide semiconductor (PMOS) transistors, insulated-gate bipolar transistors (IGBTs), Silicon Carbide (SiC) or Gallium Nitride (GaN) components and, in general, high-power devices represent areas where solutions as described herein can be advantageously applied.

As noted previously, performing burn-in testing of (integrated circuit) semiconductor devices either at wafer level and/or after die packaging is generally known in the art.

Reference is made PCT Application WO 1994/019699 A1, incorporated herein by reference, which discloses an arrangement wherein a bare die can be burn-in tested without first packaging the die. Burn-in testing of the bare die has the benefit of saving packaging efforts. For multiple die packages, burn-in testing of the bare die has the benefit that each individual die can be burn-in tested separately from the package.

Reference is also made to United States Patent Application Publication No. 2003/0052319 A1, incorporated herein by reference, which discloses a fixture that facilitates integrated circuit device probing, testing and burn-in performed in parallel before device packaging. A multiple die carrier has insets for holding dies with respect to a probe tip substrate, which has an array of contacts arranged to contact test pads on the dies to be tested within the die carrier. The fixture has locking mechanisms to hold a top cover, the die carrier and the probe tip substrate together so as to be stable during testing and burn-in. That is, the dice are placed in a wafer carrier and contacted by pins placed on an element that is in turn contacted by a testing machine on a bottom surface to transmit electrical signals for die testing. The dice are contacted and kept in position via pogo-pins (plural pins may be provided for each individual die) placed in the top cover.

United States Patent Application Publication No. 2023/0160949 A1, incorporated herein by reference, discloses a testing machine for singulated die burn-in configured to handle a die carrier and apply adequate stresses via an automated test system that comprises a handler in turn comprising a plurality of handler pickers and/or spinner pickers. The handler pickers and/or spinner pickers are adapted to each pickup one electronic component, with at least one processing station for processing one of the electronic components, a first carrier, a second carrier, and a test unit, for testing singulated electronic components located on a carrier.

Burn-in testing is also the subject-matter of extensive non-patent literature.

By way of example, reference is made to Maerz, et al., “High Dynamic Stress on SiC Trench MOSFET Body Diodes and their Behaviour”, PCIM Europe 2018; International Exhibition and Conference for Power Electronics, Intelligent Motion, Renewable Energy and Energy Management, Nuremberg, Germany, 2018, pp. 1-8, incorporated herein by reference, which discloses SiC trench MOSFET body diodes being investigated under high dynamic stress during reverse-recovery and in parallel configuration of a power module.

High-performance IC parallel test and reliability screening systems utilizing full-wafer contact technologies to test and burn-in devices at the wafer level available under the commercial designation FOX^{TM} Die Pak® Carrierare presented at the website www.aehr.com.

Throughout this description various acronyms are used that are used by those of skill in the art to define various types of stress conditions that may be applied during burn-in tests.

For immediate reference, some of these acronyms are reported below along with the associated technical definitions: HTGB: High Temperature Gate Bias; HTRB: High Temperature Reverse Bias; BDS: Body Diode Stress; DRB: Dynamic Reverse Bias; DGS: Dynamic Gate Stress; and WLBI: Wafer Level Burn In (HTRB HTGB).

To summarize, conventional solutions are known that: essentially operate either at wafer level or package level (but covering only certain types of stress in mass production: HTRB/HTGB, for instance); may use pressured wafer probe cards that are “per product” specific (and address HTRB/HTGB only); involve a Known Good Die (KGD) test performed as a final test (essentially like Automated Testing equipment (ATE)) normally at a single site or in a turret handler to validate key test parameters with a short test time.

These known solutions exhibit various drawbacks: conventional setups for Wafer Level Burn In (WLBI), with full wafer single/dual touch, for instance, can be used for HTRB/HTGB static burn-in (BI) but have limitations in terms of high voltage and high power; conventional wafer level solutions may lead to a significant reduction of parallelism; dedicated tools applying pressurized gas surrounding the contacts can be used to counter undesired electric discharges when applying high voltages/currents; at a package level, the distance between electrodes may be large enough to prevent arching, but fails are more costly, especially in the case of modules, in so far good dice being undesirably discarded together with defective dice, which adversely affects final test yield; applying high temperature may be limited by dice oxidation; and DRB test is not feasible at wafer level due to parasitic impedance.

The foregoing may explain why no integrated systems are currently available in the market operating at die level as desirable: in fact, die level (DL) dynamic stress testing appear to offer some advantages that can be more evidently perceived with wafer gross increase.

Such advantages include: only ultimately “good” devices can be stressed; defects are captured after wafer sawing; the test setup can be isolated to counter oxidation via inert gas such as N₂ so that application of high voltages is supported via a pressurized environment; the capability of dissipating high power is available; productivity is high (nearly ten times in comparison with WLBI); and combined stress such as BDS (including high power stress of stabilized threshold voltage, VTH SiC key parameters and body diode defects screened), DRB, HTRB/HTGB static BI (of gate oxide, for instance) can be applied.

Solutions as described herein can be used to apply various types of stress/test conditions to devices at die level, for instance using an apparatus/equipment which accepts “sawn” wafers as an input and returns reconstructed wafers or dice in tape as an output.

Such apparatus (or equipment: for the purposes herein these two terms are used as synonyms) can include plural stress/test stations connected by a handling infrastructure. Each station applies a specific type of stress/test under desired selected conditions (maintaining temperature at a pre-defined value, for instance). In fact, burn-in involves applying a stress aimed at activating defects and stress conditions can be identified by the combination of several parameters: current, voltage, energy, temperature and time just to mention the most common.

While higher values of stress parameters make stress more effective, certain electrical quantities cannot exceed limits imposed by device reliability. Also, test duration should be kept as short as possible to reduce costs.

Solutions as described herein provide an apparatus configured to combine several types of stress/test in a single insertion at die level to improve product quality and reliability.

For instance, in solutions as described herein: dice are placed in a carrier with a mechanically actuated lid provided with pogo pins, which keeps dice in a desired position while facilitating application of an adequate force to the pogo pins; a “universal” carrier type can be adopted (as a shuttle to convey dice through plural test stations) together with a lid that can be used for plural die types (the carrier-lid combination providing such a shuttle can be referred to as “sandwich”); the number of times a lid is placed on a carrier is limited (ideally just one time) and dice pads are preserved from damages due to pogo pins; the presence of a pressurized gas in the sandwich facilitates applying very high voltages to device pads without causing undesired electrical discharges; a thermal management feature facilitates letting (very) high currents flow through the devices without generating excessive junction temperatures; stress/test conditions being applied at die level facilitates activating of defects and identifying failing parts before assembly, thus saving money (especially in the case of modules); injecting an inert gas (nitrogen, N2 gas, for instance) counters undesired dice oxidation.

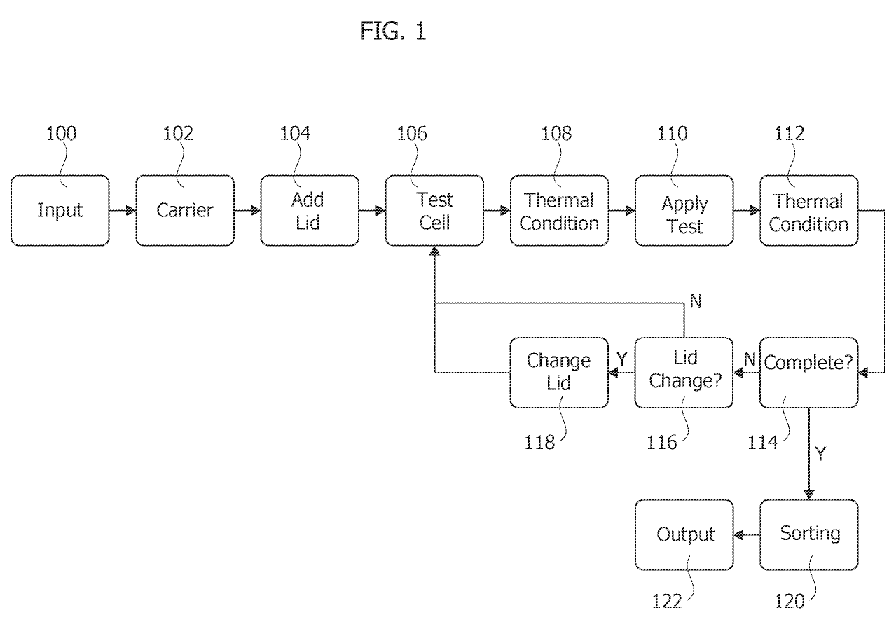

FIG. 1 is a flow-chart that illustrates a possible sequence of steps in an exemplary method for applying stress at die level in burn-in testing of integrated circuit semiconductor devices according to solutions as described herein.

It will be otherwise appreciated that the sequence of steps of FIG. 1 is merely exemplary and non-limiting in so far as: one or more process steps illustrated in FIG. 1 can be omitted, performed in a different manner (with other tools and apparatus, for instance) and/or replaced by other steps; additional process steps may be added; and/or one or more process steps can be carried out in a sequence different from the sequence illustrated.

The blocks in the flow-chart of FIG. 1 are illustrative of the following steps:
Step 100 – a sawn wafer comprising a plurality of dice (referenced as D in various figures discussed in the following) is input to the process;
Step 102 – the dice in the sawn wafer are moved to a carrier (referenced as 10 in various figures discussed in the following);
Step 104 – a lid (referenced as 12 in various figures discussed in the following) is placed on the carrier 10 to provide a carrier-lid shuttle combination referred to as “sandwich” (as described in the following);
Step 106 – the sandwich is moved to a test cell;
Step 108 – the sandwich is thermally conditioned, namely warmed-up or cooled-down, in view of the stress/test to be applied;
Step 110 – stress/test is applied;
Step 112 – sandwich is thermally conditioned, namely cooled-down or warmed-up (in view of stress/test as applied) Step 114 – test completed? Step 116 – if test is not completed (outcome N in step 114) a check is made as to a lid change being contemplated;
Step 118 – in response to lid change contemplated (outcome Y in step 116), the lid 12 is changed and process evolves again to step 106, which else occurs directly in response to outcome N in step 116 – no change of lid contemplated;
Step 120 – dice sorting in response to test completed (outcome Y in step 114);
and Step 122 – (tested) parts resulting from dice sorting moved to output media (carrier), which can be of different types (reconstructed wafer, tape, and so on).

What is exemplified in block 110 in FIG. 1 can in fact include applying several types of test/stress.

The whole process can be advantageously carried out on a single apparatus referenced as 1000 in various figures discussed in the following.

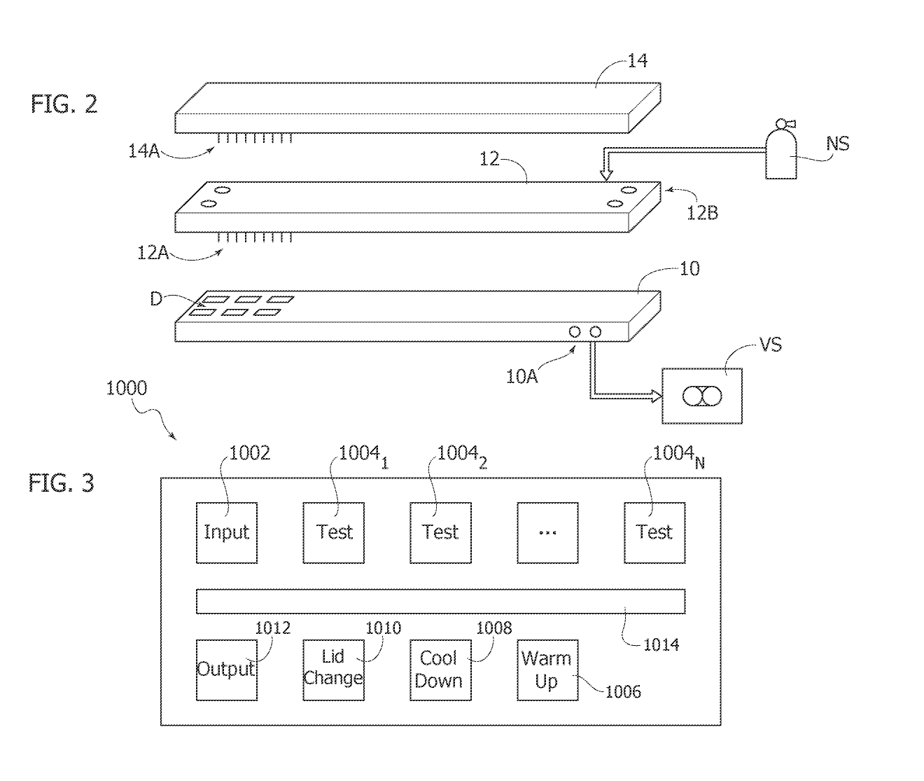

FIG. 2 is an exploded perspective view illustrative of a possible implementation of a carrier-lid combination (“sandwich”) to be used in solutions as described herein as a sort of shuttle to convey devices under test (dice D) through plural stress/test stations in the apparatus 1000.

Advantageously, these devices are left in place in the carrier where they are arranged when loaded into the testing apparatus – which counters undesired damage that may arise if the devices are re-arranged – with only the lid (possibly, but not imperatively) changed.

In FIG. 2, reference 10 denotes a carrier (a laminated, thermally and electrically conductive body, for instance) provided with locations such as slots configured to host integrated circuit semiconductor devices (dice) D from a “sawn” semiconductor wafer.

Components such as p-channel metal-oxide semiconductor (PMOS) transistors, insulated-gate bipolar transistors (IGBTs), Silicon Carbide (SiC) or Gallium Nitride (GaN) components and, in general, high-power devices can be cited as non-limiting examples of devices (dice) D that can be handled using solutions as described herein.

It is otherwise noted that, while intended to be hosted by the carrier 10, the dice D per se are not part of the sandwich (shuttle) according to solutions as described herein.

Advantageously, the carrier 10 can be provided with connections 10A to a source VS of sub-atmospheric pressure (pressure less or lower than that of the atmosphere, namely “vacuum”) of any known type (a vacuum pump or line, for instance) to which the sandwich according to solutions as described herein can be connected during testing.

Reference 12 in FIG. 2 denotes a lid (again, thermally and electrically conductive body, for instance) configured to be coupled to the carrier 10 having the dice D arranged thereon.

The lid 12 is provided with contact pins (for instance, so-called “pogo” pins) 12A configured to make electrical contact to respective contact formations (pads) – not visible for scale reasons and simplicity – on the dice D and the carrier 10.

The lid 12 is provided with connections 12B to a source NS (a gas cylinder or facility line) of flushing and pressurization gas such as an inert gas (nitrogen N₂ gas, for instance), to which the sandwich according to solutions as described herein can be connected during testing.

FIG. 2 highlights the presence of a so-called redistribution layer (RDL) 14 intended to cooperate with further contact pins 14A. For instance, the contact pins 14A can be provided on the upper surface of the lid 12 and the RDL can be implemented as a printed circuit board (PCB) intended to be contacted by pins 16A (not visible in FIG. 2, but represented in FIG. 5 and FIG. 7) carried by test cell equipment 16 as discussed in the following.

In a manner known to those of skill in the art, the redistribution layer 14 is intended to facilitate interfacing (that is, providing electrical contact for) a (fixed) array of pins 16A in the test cell 16 with different distributions of contact formations (pads) on the dice D in the carrier 10.

Even if not visible in the other figures and not explicitly referred to in the rest of this detailed description for brevity and ease of representation, the redistribution layer (RDL) 14 can be assumed to be provided in order to co-operate with the lid 12 (and thus with the sandwich comprising the carrier 10 and the lid 12) in order to facilitate interfacing with the test cell 16.

Consequently, for simplicity (and unless the context indicates otherwise) the designation “sandwich” (or “shuttle”) will apply to the combination of the carrier 10 configured to have the dice D arranged thereon and the lid 12 coupled therewith and/or other mechanical components (not visible for simplicity) to facilitate clamping and robotization, by assuming that a redistribution layer (not visible for simplicity) can be provided to facilitate interfacing with the test cell 16.

Vacuum from the source VS is used to keep the devices (dice D) in place on the carrier 10 when the lid 12 is not clamped.

As further discussed in the following, gas connections 12A on (top of) the lid 12 facilitate pressurization (in high-voltage tests, for instance) and/or flushing (in high-current tests, for instance) using gas (an inert gas such as nitrogen) from the source VS.

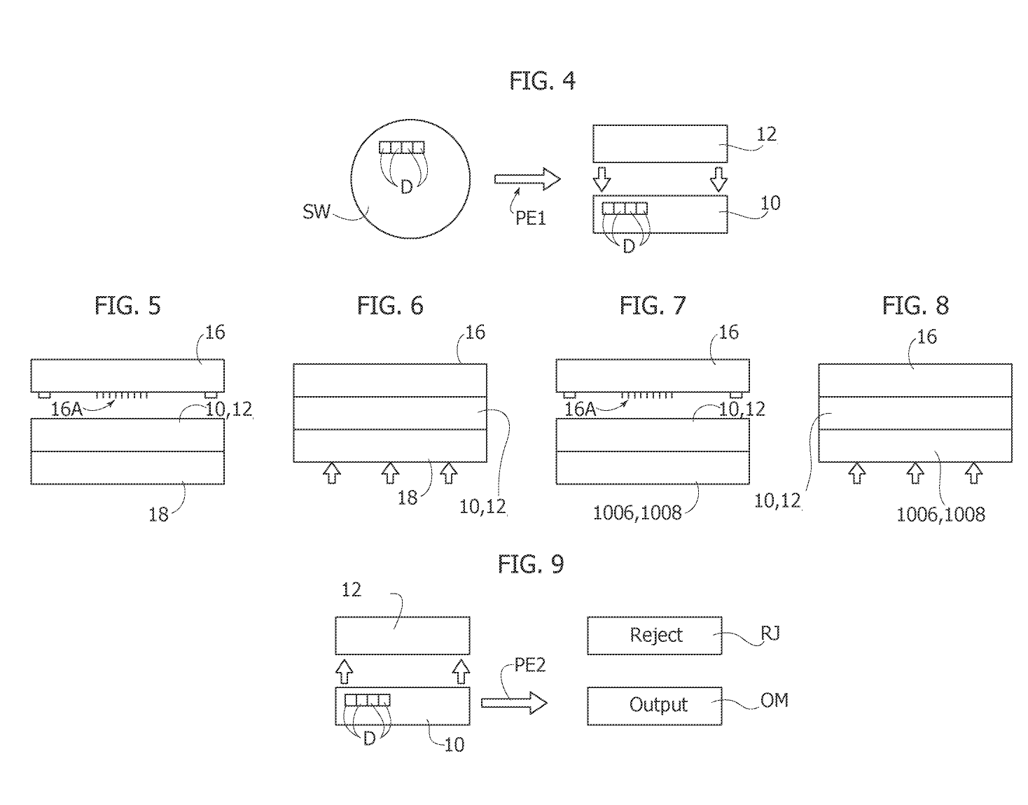

FIG. 3 is a diagram illustrative of a possible functional arrangement of stages/cells in an apparatus 1000 configured to carry out the process exemplified in the flow-chart of FIG. 1 with the devices under test (dice D) conveyed through various stress/test station using as a conveyance shuttle a sandwich comprising a carrier 10 and a lid 12 as discussed previously.

The block 1002 in FIG. 3 is representative of an input stage where a sawn wafer comprising a plurality of dice D is input to the process and the dice D in the sawn wafer are moved to a carrier 10 and a lid 12 is placed on the carrier 10.

The blocks 1004₁, 1004₂, …, 1004_{N} in FIG. 3 are representative of cells where (various types of) stress/test are applied to the sandwiches having the dice D therein, with or without thermal conditioning as possibly provided by warm-up/cool-down features 1006, 1008 to be finally advanced (possibly after lid change in a lid changer indicated by reference number 1010) towards an output stage 1012 where parts resulting from dice sorting are moved to an output carrier (reconstructed wafer, tape, and so on) as discussed previously.

Reference 1014 in FIG. 3 indicate an automation system (“robotization”) that coordinates conveyance of the devices under test through the apparatus 1000 and operation of the apparatus 1000 to apply to these devices various stress/test conditions as desired.

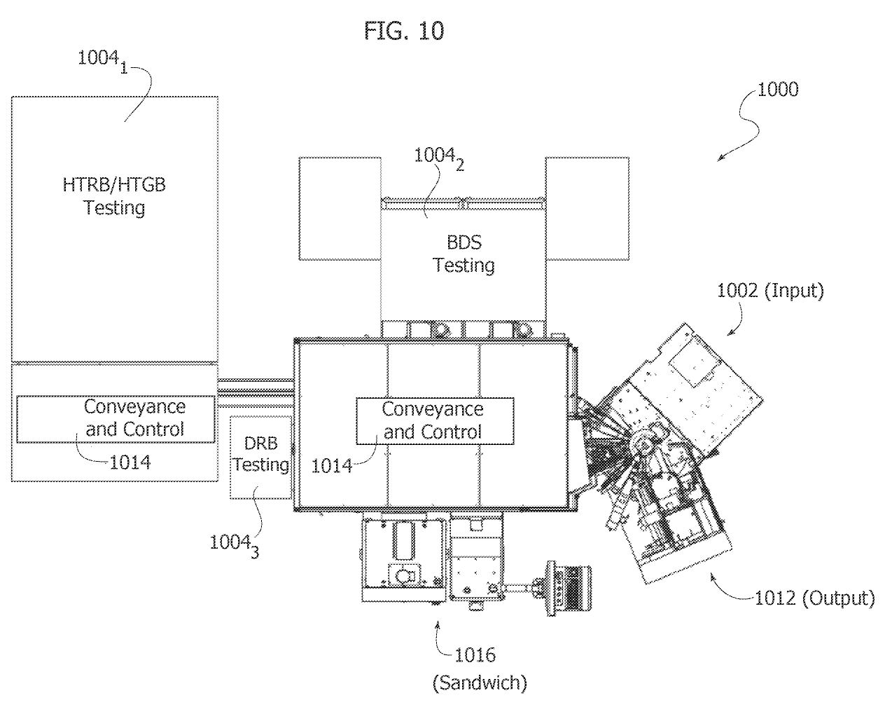

FIGS. 4-9 are schematically illustrative of steps in a process as exemplified in the flow-chart of FIG. 1 that can be performed on devices under test (dice D) arranged in a sandwich 10, 12 as exemplified in FIG. 2 in the apparatus 1000 as exemplified in FIG. 3.

FIG. 4 is exemplary of operation of an input stage or station (block 1002 in FIG. 3) where dice D are taken from a sawn wafer SW and placed in a carrier 10 (via picker equipment PE1 of a type known per se) which is then covered with a lid 12 to form the sandwich.

The sandwich is then used as a conveyance (transport) media and contactor as a shuttle to advance the dice D through multiple different test stations or cells (1004₁, 1004₂, …, 1004_{N} in FIG. 3).

FIGS. 5 and 6 are exemplary of operation of the cells where the sandwich 10, 12 co-operate with test cell equipment (not visible in its entirety for simplicity) that includes a Prober Interface Board (PIB) 16 that, at first disengaged from the sandwich 10, 12 (FIG. 5), “touches down” on the sandwich 10, 12 (FIG. 6) so that contact pins 16A of the PIB 16 establish (advantageously, via a redistribution layer) electrical contact to the pins 12A and thus to the dice D on the carrier 10, with thermal control possibly associated with such an arrangement indicated by reference numeral 18.

In that way, electrical (voltage/current) stimulation signals can be applied to the dice D hosted in the carrier 10, with reaction signals collected therefrom used to identify possibly damaged (faulty) dice.

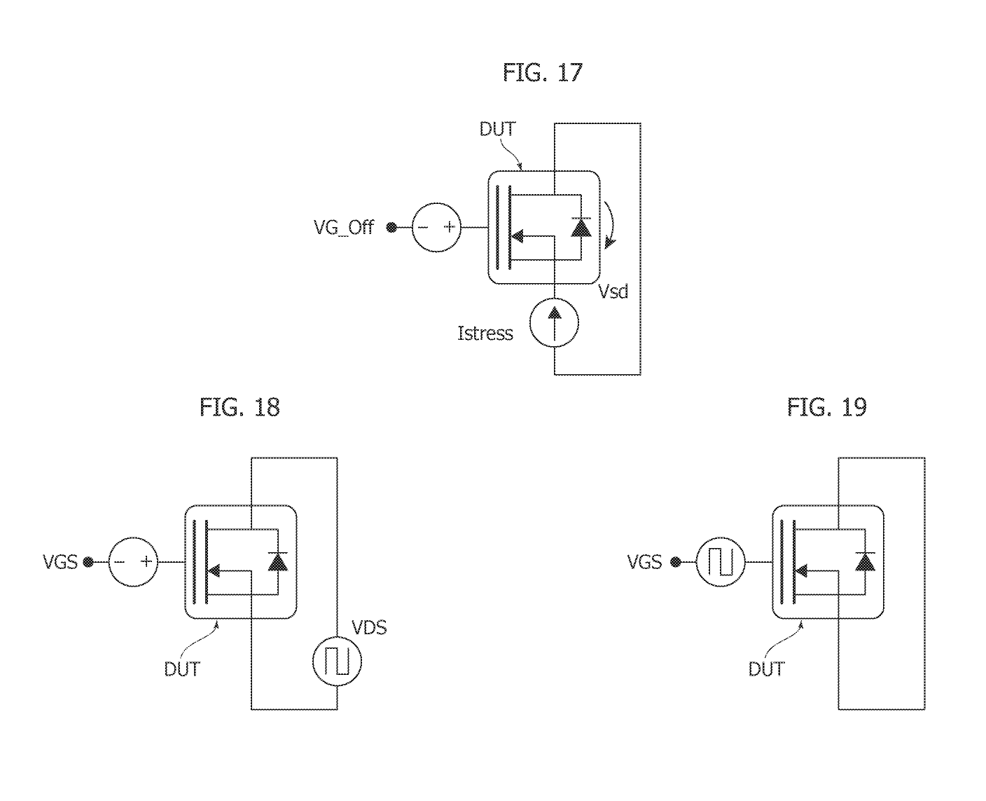

Possible examples of stress/test conditions involving stimulation signals applied to and reaction signals collected from dice D will be given in connection with FIGS. 15-19, being otherwise understood that criteria for identifying possibly damaged (faulty) dice D are known to those of skill in the art and, per se, are of no specific momentum for the solutions described herein.

Contact actuation between the sandwich 10, 12 and the test equipment (the PIB) 16 involves urging the sandwich 10, 12 with the dice D hosted therein and the PIB 16 mutually against each other and possible thermal conditioning applied (in a manner known per se) through a chuck 18 with an associated actuation.

The test equipment 16 can carry inert gas (nitrogen, for instance) connections towards the sandwich (to be coupled to the gas connections 12A on the lid 12) in order to facilitate gas pressurization and/or flushing as discussed previously.

FIGS. 7 and 8 are exemplary of operation of the cells where the sandwich 10, 12 co-operate with test equipment 16 along the same line of FIGS. 5 and 6, namely with the sandwich 10, 12 with the dice D and the test equipment 16 urged against each other. In FIGS. 7 and 8 thermal conditioning is assumed to be applied (via a plate, for instance) in a climatic chamber such as blocks 1006 or 1008 in FIG. 3.

As illustrated in FIG. 9, in an output stage or station (referenced as 1012 in FIG. 3) the lid 12 can be separated from the carrier 10 and the dice D removed therefrom (via picker equipment PE2 of a known type, which may be notionally the same picker equipment PE1 of FIG. 4), with the dice D found – in a manner known per se – to be faulty transferred to a reject destination RJ (a reject bin, for instance), while “good” dice are retained and transferred to an output media OM for further handling.

The apparatus 1000 as proposed herein includes a plurality of stress/test stations 1004₁, 1004₂, …, 1004_{N} that are of different types, for instance of three different types (that is, at least one first test type and at least one second test type, different from the first test type) configured to perform different types of tests such as, for instance: BDS, with continuous flow of nitrogen for cooling during the test; HTGB and HTRB (a same station is able to perform both tests), with nitrogen introduced at the beginning of the test for pressurization and then released at the end of the test; and DRB and DGS (again a same station is able to perform both tests) with nitrogen introduce at the beginning of the test for pressurization then released at the end of the test.

Of course, referring to three stations and five types of stress/test condition is merely exemplary: modular architecture of the apparatus 1000 facilitates adding and/or replacing stations to perform other types of tests.

Gas such as nitrogen can be supplied via a source NS (a cylinder or a facility line) that is external to the apparatus 1000.

When a sandwich 10, 12 is loaded in a test station 1004₁, 1004₂, …, 1004_{N} in the apparatus 1000, the associated electrical lines for the stimulation/reaction signals and the gas (nitrogen) supply lines are connected via dedicated connectors. At the end of the test, both the electrical lines and the gas supply lines are disconnected, to be re-connected again at another, next station 1004₁, 1004₂, …, 1004_{N}.

Advantageously, gas pressurization can be preceded by a flushing phase with open outlet valves to remove oxygen and other non-inert gases that may be present in the sandwich (microchamber MC in FIG. 14).

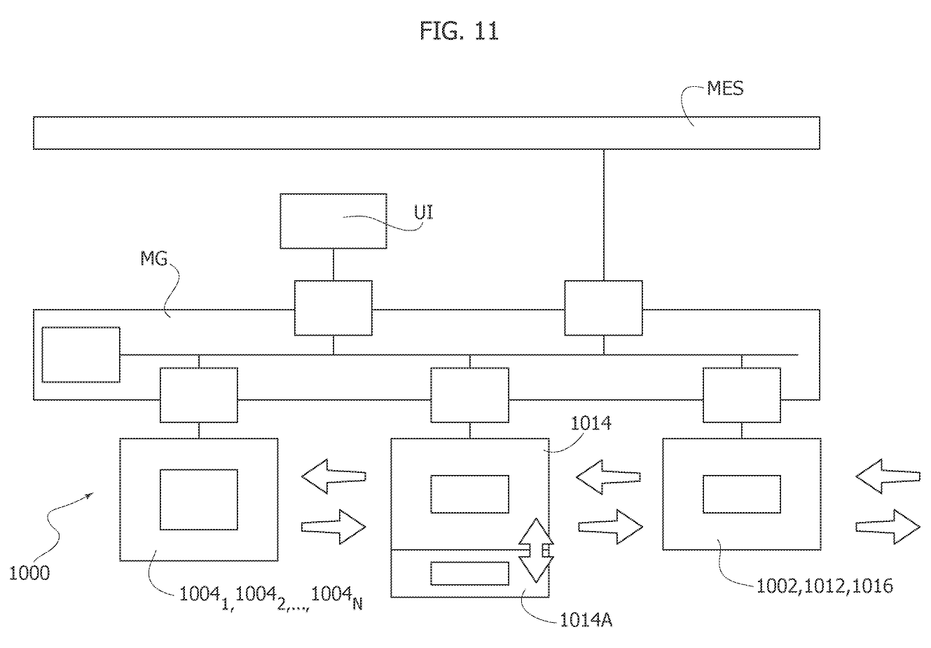

FIG. 10 is a plan view of a possible implementation of the apparatus 1000 according to functional architecture as exemplified in FIG. 3 and comprising three test cells 1004₁ (HTRB/HTGB, for instance), 1004₂ (BDS, for instance), and 1004₃ (DRB, for instance).

The apparatus 1000 as illustrated in FIG. 10 includes an input stage 1002 for a sawn wafer SW, an output stage 1012 (tape and reel/reconstructed wafer, for instance) plus conveyance and control robotics (represented by blocks 1014) and a sandwich input/output stage 1016 suited to be implemented based on existing die level pick and place handler equipment available on the market.

Advantageously, the input and output stages 1002 and 1012 can be integrated to a common turret equipment thus leaving space available for the sandwich input/output stage 1016 configured to manage load and unload of sandwiches.

The apparatus 1000 as illustrated in FIG. 10 is suited to implement (with the robotics 1014 providing conveyance of parts/components and handling thereof within the apparatus) a test process flow that implements a sequence as generally exemplified in the flow-chart of FIG. 1.

More specifically: empty sandwiches 10, 12 and the sawn wafer SW (that is, an array of individual dice D to be tested) can be input to the apparatus 1000 via the stage 1016 and a respective handler in the input stage 1002; the robotics/robotization 1014 can move sandwiches having the dice D arranged therein (via handler equipment such as PE1 in the input stage 1002) through the test stations (or cells) 1004₁, 1004₂, 1004₃; the robotization 1014 can put a lid 12 on a carrier 10 thus composing a sandwich having devices D arranged therein; once testing is completed in a first test station or cell (the test cell 1004₁, for instance), the robotization 1014 can advance the sandwich to another test cell (the test cell 1004₂, for instance), possibly after removing the lid 12 leaving just the carrier 10 in a handler and replacing that lid with another lid to re-compose another sandwich to be advanced to the other test cell; and once a testing is completed in that other test station or cell (the test cell 1004₂), the robotization 1014 can advance the sandwich to a further test cell (say, the test cell 1004₃, for instance) possibly after removing again the lid 12 leaving just the carrier 10 in a handler and replacing that lid with another lid to re-compose another sandwich to be advanced to the further test cell.

Operation as described above can continue until testing in plural stations or cells is completed as planned, and a handler unloads the devices D from the carrier 10 after removing the associated lid.

At that point, as exemplified in FIG. 9, devices D are removed from the handler and a picker device (see reference PE2 in FIG. 9) in the output stage or station 1012 steers faulty (fail) devices to the reject bin RJ and devices tested to be “good” to the output media OM.

The robotization 1014 is configured to put a lid 12 on an “emptied” carrier 10 composing an empty sandwich that can be returned to the stage 1016.

To summarize, FIG. 10 is illustrative of an apparatus 1000 for testing (integrated circuit, IC) semiconductor dice, with such apparatus 1000 comprising: a loading station 1002 (possibly equipped with a picker such as the picker PE1 in FIG. 4) configured to receive arrays of semiconductor dice under test D; and a plurality of test stations 1004₁, 1004₂, …, 1004_{N} wherein each test station in the plurality of test stations 1004₁, 1004₂, …, 1004_{N} is configured to perform at least one respective test by applying under controlled environmental conditions respective individual electrical stimulation signals to semiconductor dice under test D and collecting therefrom respective individual reaction signals in response to the respective individual electrical stimulation signals applied thereto.

As illustrated in FIG. 10, each test station in the plurality of test stations 1004₁, 1004₂, …, 1004_{N} is configured to identify as defective (in a manner known per se to those of skill in the art) individual semiconductor dice under test D that fail to pass said at least one respective test.

As illustrated in FIG. 10, a conveyance structure (the conveyance and control robotics 1014, possibly equipped with “sandwiches” 10, 12 as discussed herein) is provided to advance the arrays of semiconductor dice under test D in a test path through the plurality of test stations 1004₁, 1004₂, …, 1004_{N} towards an unloading station 1012 (possibly equipped with a picker such as the picker PE2 in FIG. 9) configured to receive arrays of semiconductor dice under test D advanced via the conveyance structure 1014 in the test path through the test stations 1004₁, 1004₂, …, 1004_{N}, and direct to a reject destination (the reject bin RJ, for instance) individual semiconductor dice under test D identified as defective.

It is noted that the apparatus 1000 as illustrated in FIG. 10 is configured to perform die-level testing, with the loading station 1002 configured to receive semiconductor wafers SW sawn into arrays of individual semiconductor dice under test D that undergo testing with respective electrical stimulation signals applied individually thereto respective individual reaction signals collected therefrom in response to the respective individual electrical stimulation signals applied.

The robotization/robotics 1014 for conveyance and control can be advantageously configured to support operation as discussed in the foregoing, performing its basic tasks of assembling/disassembling sandwiches and feeding sandwiches to the test cells (test positions) by facilitating carrier input/output, sandwich input/output, possible change of lids by resorting to a modular approach, in a fully configurable (process step configurable) and expandable manner to include one or more optional modules that take care, for instance, of possible heating/cooling of sandwiches moved between sections of the apparatus 1000.

The apparatus 1000 discussed herein comprises a plurality of test stations 1004₁, 1004₂, …, 1004_{N} that may be advantageously configured to apply to semiconductor dice under test D individual electrical stimulation signals comprising: voltages of at least 1000V, optionally at least 1200V (optionally below 2500V, thus optionally between 1200V and 2500V); and/or currents of at least 8A, optionally at least 10A (optionally below 14A, thus optionally between 10A and 14A).

The apparatus 1000 discussed herein comprises a plurality of test stations 1004₁, 1004₂, …, 1004_{N} that may be advantageously configured to apply to semiconductor dice under test D respective individual electrical stimulation signals under controlled environmental conditions that comprise a temperature above 120° C., optionally above 150° C. (optionally below 200° C., thus optionally between 150° C.and 200° C.).

The apparatus 1000 discussed herein comprises a plurality of test stations 1004₁, 1004₂, …, 1004_{N} that may be advantageously configured to apply controlled environmental conditions to semiconductor dice under test by supplying gas NS towards the semiconductor dice under test.

Advantageously, gas supplied towards the semiconductor dice under test D may include: inert gas, preferably nitrogen; and/or pressurized gas; and/or a flushing gas flow.

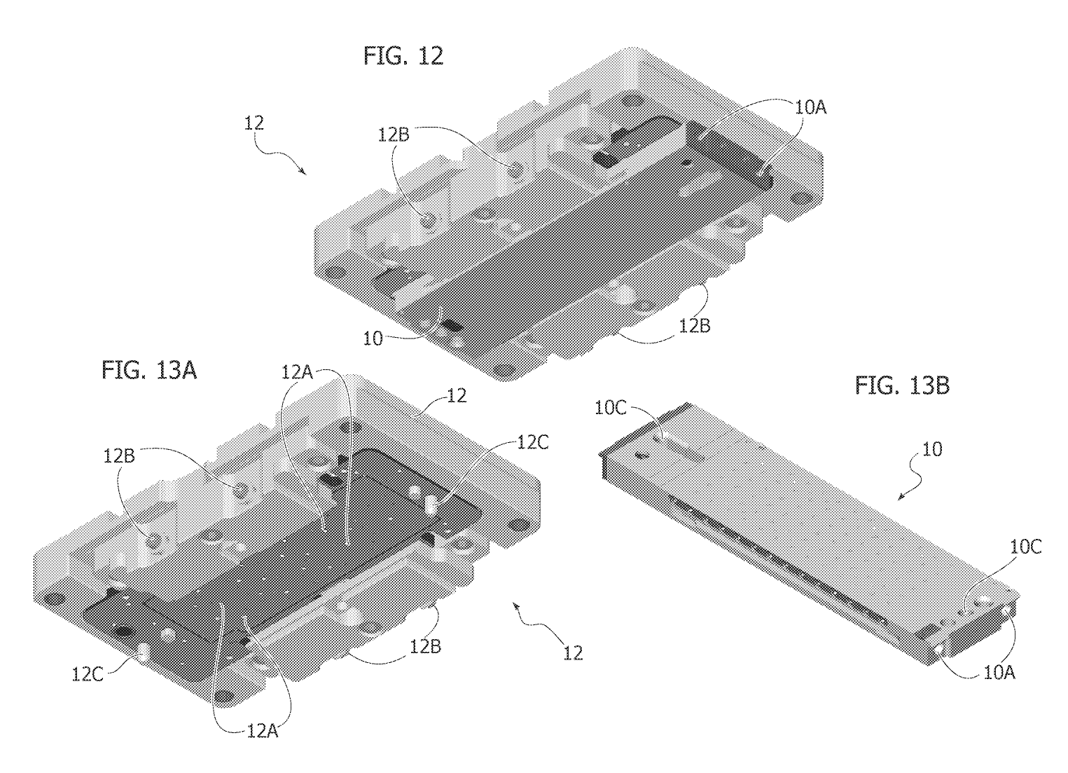

FIG. 11 is exemplary of the possibility of configuring the apparatus 1000 as illustrated in FIGS. 3 and 10 based on high-level architecture wherein the robotization 1014 (with an associated stocker 1014A), the tester equipment (cells 1004₁, 1004₂, …, 1004_{N}) and the various handler devices providing wafer, dice/ cassette and sandwich loading and unloading (in stages 1002, 1012 and 1016) can be configured to communicate under the supervision of a user interface UI via a lightweight messaging protocol MG within the framework of a manufacturing execution system (MES) that monitors, tracks, documents, and controls the process of manufacturing integrated circuit semiconductor devices.

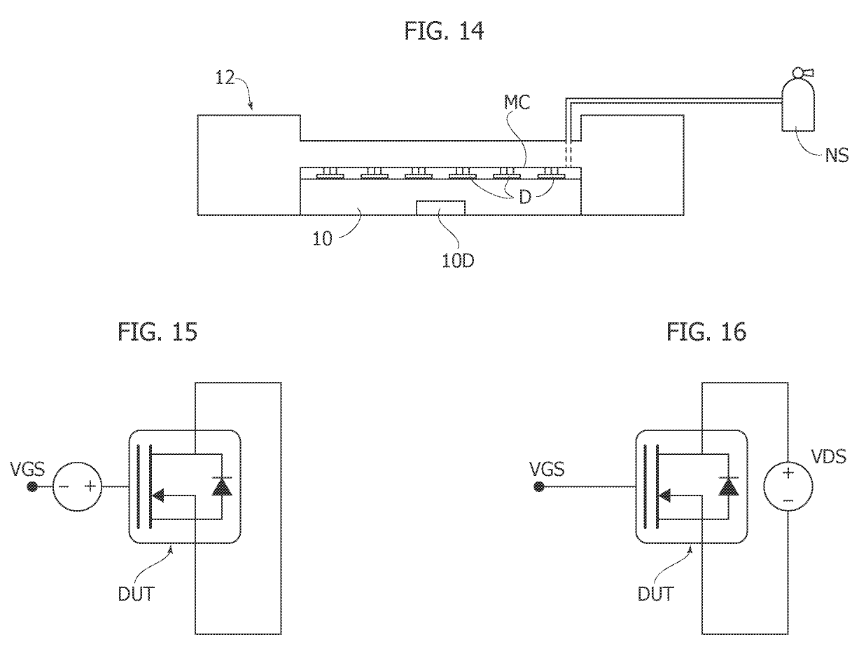

FIGS. 12, 13A, 13B, and 14 illustrate more in detail an advantageous way of implementing a “sandwich” (carrier 10 and lid 12) according to solutions as described herein.

FIGS. 13A, 13B illustrate separately the carrier 10 and the lid 12 that are illustrated in FIG. 12 when mutually coupled in a sandwich combination. FIG. 14 is a cross-sectional view along line XIV-XIV in FIG. 12.

As noted, a redistribution layer (see reference 14 in FIG. 2) can be provided order to facilitate establishing electrical contact between the contact pins 16A of a cell test equipment 16 and the pins 12A of the lid 12 and thus the dice D on the carrier 10. Such an arrangement facilitates applying to the dice D (voltage/current) stimulation signals and possibly collect therefrom reaction signals that can be used to identify possibly damaged (faulty) dice D.

The discussion related to FIGS. 12, 13A, 13B and 14 focuses on the interaction between the carrier 10 and the lid 12, which is intended to facilitate achieving a number of advantages, namely: the dice D are placed in the (thermally conductive) carrier 10 with the lid 12 that is configured to be mechanically handled (positioned, removed and re-positioned via the robotization 1014, for instance) and provided with (e.g., pogo) pins 12A so that the dice D are kept in a desired position while facilitating application of an adequate force to the pins; a “universal” carrier 10 can be adopted together with lids 12 that can be used for plural different die types, in different sandwich (carrier-lid) combinations; the number of times a lid 12 is placed on a carrier 10 is limited (ideally one) so that dice pads are preserved from damages due to pogo pins 12A; a pressurized gas can be injected into the sandwich, via connections 12B in the lid, for instance, to form a pressurized micro-chamber MC, which facilitates applying very high voltages to the devices D without causing undesired electrical discharges; the pressurized gas supplied to the (micro-chamber MC in) sandwich being an inert gas (nitrogen N₂ gas, for instance) counters undesired oxidation of the dice D; a thermal management feature (including a thermal sensor 10D integrated in the carrier 10, for instance – see FIG. 14) facilitates applying (very) high current flows through the devices D without generating excessive junction temperatures.

As illustrated in FIGS. 12, 13A, 13B and 14 the lid 12 is advantageously shaped channel-like (with a C-shaped or H-shaped cross section: see FIG. 14) so that the carrier 10 with the dice D arranged thereon can be inserted into the lid 12 with the carrier 10 “embraced” by the lid 12.

In that way, the carrier 10 and the lid 12 can be clamped (sandwiched) together – possibly with mechanical clamping force applied via the test cell 16 – forming within the sandwich structure the (micro)chamber MC around the dice D that can be pressurized with gas from the source NS.

Precise form coupling of the carrier 10 and the lid 12 (possibly facilitated by mating of complementary coupling formations such as pins and holes 10C and 12C) makes such a chamber gas-tight, which facilitates creating a sort of sterile environment filled with inert gas (nitrogen, for instance) that counters undesired device oxidation (dice D) at high temperature.

Gas flushing may facilitate cooling the carrier 10 and the dice D thereon.

A high-pressure environment as provided by gas supplied into the chamber MC counters undesired electrical arching with high voltages applied.

To summarize, a “sandwich” 10, 12 as described herein is exemplary of a shuttle device that can be advantageously used in the conveyance structure (the robotics or robotization 1014) of the apparatus 1000 described herein with such shuttle device comprising: a die carrier 10 configured to host an array of semiconductor dice under test D; a lid 12 having an array of contact tips 12A configured to contact dice D in the die carrier 10 and apply respective individual electrical stimulation signals to these dice D in the die carrier 10 and collect therefrom respective individual reaction signals in response to the respective individual electrical stimulation signals being applied.

A lid 12 as described herein is configured to be coupled to the die carrier 10 to form a chamber MC between the lid 12 and the die carrier 10 provided with a gas supply pathway (the gas connections 12B) towards the chamber MC.

Advantageously, the die carrier 10 and the lid 12 may be configured to be mutually coupled: in a gas-tight coupling configuration with pressurized gas supplied (from the source NS) into the chamber MC; and/or in a gas permeable coupling configuration (with outlet valves opened, for instance) in order to facilitate a flushing gas flow through the chamber MC.

As noted, criteria for identifying possibly damaged (faulty) dice D are known to those of skill in the art and, per se, are of no specific momentum for the solutions described herein.

FIGS. 15-19 are nonetheless illustrative of various exemplary tests that can be advantageously carried out on an (integrated circuit) semiconductor device under test, DUT – here represented for simplicity by a MOSFET transistor with the respective body diode shown – using apparatus 1000 as described herein.

FIG. 15 is exemplary of a High Temperature Gate Bias (HTGB) test wherein a gate source voltage VGS is applied to the DUT. This test involves a high temperature stress applied and benefits from being performed in an inert gas (nitrogen, for instance) chamber. This is essentially a static stress intended to activate oxide-related defects.

FIG. 16 is exemplary of a High Temperature Reverse Bias (HTRB) test wherein a drain-source voltage VDS is applied to the DUT. This test again involves a high temperature stress applied and benefits from being performed in an inert gas (nitrogen, for instance) chamber. This test also involves a high voltage stress applied and benefits from being performed in a pressurized chamber (with high pressure applied with a gas such as nitrogen, for instance). Again, this is essentially a static stress that is intended to activate junction-related defects.

FIG. 17 is exemplary of a Body Diode Stress (BDS) test wherein a high stress current Istress is forced to flow though the source-drain current flow path through the DUT (MOSFET transistor) with open gate (VG_Off). This test involves a high current stress applied and is intended to activate junction-related defects. During the test, power consumption in the device (DUT) is high and the test benefits from being performed with thermal regulation (sensor 10D in FIG. 14 and associated thermal conditioning: see 18 in FIG. 6, for instance). High current values for Istress may result in measurements being undesirably affected by parasitic resistances unless a so-called Kelvin method is used, which benefits from additional contact points being provided (via the pins 12A in the lid 12, for instance) to facilitate accurate measurements.

FIG. 18 is exemplary of a Dynamic Reverse Bias (DRB) test wherein a high-frequency alternate stimulation signal is applied across the source-drain path of the DUT. This test involves the combination of a high-frequency stress, a high-slew rate stress, and a high-voltage stress applied and benefits from being performed in in a pressurized chamber (with high pressure applied with a gas such as nitrogen, for instance). This is essentially a combined dynamic stress that is intended to activate oxide-related defects.

Finally, FIG. 19 is exemplary of a Dynamic Gate Stress (DGS) test wherein a high-frequency alternate stimulation signal is applied to the gate of the DUT. This test involves a high-frequency stress and a high-slew rate stress and again benefits from being performed in in a pressurized chamber (with high pressure applied with a gas such as nitrogen, for instance). This is essentially a dynamic stress that is intended to activate junction-related defects.

The tests of FIGS. 15-19 are exemplary of tests that can be caried out (at die level) on semiconductor dice under test using an apparatus 1000 as discussed previously with a method including: supplying arrays (sawn wafer SW) of semiconductor dice under test DUT to the loading station 1002 in the testing apparatus 1000; advancing via the conveyance structure (robotization 1014) in the testing apparatus 1000 the arrays of semiconductor dice under test DUT in a test path through a plurality of test stations 1004₁, 1004₂, …, 1004_{N}, wherein each test station in the plurality of test stations 1004₁, 1004₂, …, 1004_{N} identifies as defective individual semiconductor dice under test DUT that fail to pass the at least one respective test; and directing to a reject destination 1012, RJ individual semiconductor dice under test DUT) identified as defective.

Testing being die-level testing may involve producing the arrays of individual semiconductor dice under test by sawing semiconductor dice wafers SW.

Advantageously, the arrays of semiconductor dice under test D are advanced in the test path through the plurality of test stations 1004₁, 1004₂, …, 1004_{N} with the arrays of semiconductor dice under test D arranged in a shuttle device (“sandwich”) 10, 12 as described herein.

Advantageously, the shuttle device 10, 12 comprises, in addition to a first lid, at least one further lid thus providing an assortment of (at least two) mutually replaceable lids 12 having respective arrays of contact tips 12A configured to contact dice D in the die carrier 10 to apply respective individual electrical stimulation signals to the dice D in the die carrier 10 and collect therefrom respective individual reaction signals in response to respective individual electrical stimulation signals being applied.

The lids 12 in the assortment of mutually replaceable lids 12 are thus couplable alternatively with a same die carrier 10 to contact dice D in the die carrier 10 and perform respective tests applying respective individual electrical stimulation signals to these dice D in the die carrier 10 and collect therefrom respective individual reaction signals in response to said respective individual electrical stimulation signals being applied without having to move the dice to another carrier.

The availability of such an assortment of mutually replaceable lids 12 thus facilitates testing wherein arrays of semiconductor dice under test (D, DUT) are advanced in a test path through different test stations in a testing apparatus 1000 with the (same) die carrier 10 (subsequently) coupled with different lids 12 in the assortment of mutually replaceable lids 12.

Solutions as described herein: facilitate providing plural stress/test conditions with a single insertion of devices under test; facilitate detecting sawing issues at die level and simplify front-end (FE) processing performed on sawed wafers; anticipate failure detection to (pre-packaged) die level from package level, thus providing improved Cost of Ownership (COO) for semiconductor manufacturing equipment (roughly 50% in comparison with wafer level, WL) and reducing equivalent footprint for a same capacity; achieve very high effective units per hour, UPH values (8K/h, for instance) and are compatible with fully robotized implementation; combine high-voltage, high-current, high-temperature stress tests in fully automated (robotics/cell controller) test cells; provide scalable solutions for medium/long test times; and facilitate applying high voltages and/or high currents using a pressurized micro-chamber.

Solutions as described herein facilitate burn-in testing of semiconductor devices that improve quality and reliability, while reducing Customer Owned Tooling (COT).

Solutions as described herein can be implemented as an integrated equipment, suited to be used in mass production, for applying medium-to-long (seconds to hours) test/stress to microelectronics devices at die level.

Solutions as described herein facilitate performing multiple tests with a single contact on the devices (dice) taking advantage of a pressurizable and thermally conductive support (“sandwich”). Test conditions applied may include high-voltage and high-temperature static tests (HTGB and HTRB), high-current static tests (BDS), as well as high-slew-rate dynamic tests (DRB and DGS).

To summarize, the apparatus 1000 as described herein comprises a loading station (see references 1002 and PE1) configured to receive arrays SW of semiconductor dice under test D, DUT and a plurality of test stations 1004₁, 1004₂, …, 1004_{N} wherein each of these stations is configured to perform at least one respective test by applying respective individual electrical stimulation signals to semiconductor dice under test D, DUT in the arrays SW of semiconductor dice under test D, DUT and collecting therefrom respective individual reaction signals in response to the respective individual electrical stimulation signals being applied thereto.

As described herein, each test station in the plurality of test stations 1004₁, 1004₂, …, 1004_{N} is configured to identify as defective individual semiconductor dice under test D, DUT in the arrays SW of semiconductor dice under test D, DUT that fail to pass said at least one respective test.

The apparatus 1000 as described herein includes a conveyance structure (see references 1014 and 10, 12) configured to advance the arrays of semiconductor dice under test D, DUT in a test path through the plurality of test stations 1004₁, 1004₂, …, 1004_{N}, and an unloading station (see references 1012 and PE2) configured to receive arrays SW of semiconductor dice under test D, DUT that are advanced via the conveyance structure in the path through the plurality of test stations 1004₁, 1004₂, …, 1004_{N}, and direct to a reject destination (see reference RJ) individual semiconductor dice under test D, DUT in the arrays SW of semiconductor dice under test D, DUT that are identified as defective.

Advantageously, at least one test station in the plurality of test stations 1004₁, 1004₂, …, 1004_{N} may be configured to apply to semiconductor dice under test D, DUT in the arrays SW of semiconductor dice under test D, DUT individual electrical stimulation signals comprising voltages of at least 1000V, optionally below 2500V, and/or currents of at least 8A, optionally below 14A.

Still advantageously, at least one test station in the plurality of test stations 1004₁, 1004₂, …, 1004_{N} is configured to apply to semiconductor dice under test D, DUT in the arrays SW of semiconductor dice under test D, DUT respective individual electrical stimulation signals at a temperature above 120° C., optionally below 200° C.

Solutions as described herein rely on a shuttle device 10, 12 comprising a die carrier 10 configured to host an array of semiconductor dice under test D as well as a lid 12 having an array of contact tips 12A configured to contact dice D in the die carrier 10, apply respective individual electrical stimulation signals to said dice D in the die carrier 10 and collect therefrom respective individual reaction signals in response to the respective individual electrical stimulation signals being applied.

As described, the lid 12 is configured to be coupled to the die carrier 10 to form a chamber MC between the lid 12 and the die carrier 10, with a gas supply pathway 12B towards that chamber MC.

Advantageously, the die carrier 10 and the lid 12 may be configured to be mutually coupled in a gas-tight coupling configuration with pressurized gas NS supplied into the aforesaid chamber MC

Still advantageously, the die carrier 10 and the lid 12 may be configured to be mutually coupled in a gas permeable coupling configuration to facilitate a flushing gas flow through the aforesaid chamber MC.

Without prejudice to the underlying principles, the details and embodiments may vary, even significantly, with respect to what has been described by way of example only without departing from the extent of protection.

The claims are an integral part of the technical teaching provided herein in respect of the embodiments.

The extent of protection is determined by the annexed claims.

1. An apparatus, comprising:
a loading station configured to receive arrays of semiconductor dice under test;
a plurality of test stations wherein each test station in the plurality of test stations is configured to perform at least one respective test by applying respective individual electrical stimulation signals to semiconductor dice under test in said arrays of semiconductor dice under test and collecting from the semiconductor dice under test respective individual reaction signals in response to said respective individual electrical stimulation signals;
wherein each test station in the plurality of test stations is configured to identify as defective individual semiconductor dice under test in said arrays of semiconductor dice under test that fail to pass said at least one respective test;
a conveyance structure configured to advance said arrays of semiconductor dice under test in a test path through said plurality of test stations; and
an unloading station configured to receive arrays of semiconductor dice under test advanced via said conveyance structure in said path through said plurality of test stations, and direct to a reject destination the individual semiconductor dice under test in said arrays of semiconductor dice under test identified as defective.

2. The apparatus of claim 1, wherein the loading station is configured to receive semiconductor wafers that have been sawn into arrays of individual semiconductor dice under test.

3. The apparatus of claim 1, wherein the loading station is configured to receive arrays of semiconductor dice under test comprising individual semiconductor bare dice.

4. The apparatus of claim 1, wherein at least one test station in said plurality of test stations is configured to supply towards said semiconductor dice under test: inert gas; pressurized gas; and a flushing gas flow.

5. The apparatus of claim 1, wherein a first test station of said plurality of test stations is configured to perform at least one respective first test and a second test station of said plurality of test stations is configured to perform at least one respective second test wherein the respective first test and the respective second test are mutually different.

6. The apparatus of claim 5, wherein the first test and second test are a test selected from the group consisting of: a High Temperature Gate Bias (HTGB) test; a High Temperature Reverse Bias (HTRB) test; a Body Diode Stress (BDS) test; a Dynamic Reverse Bias (DRB) test; and a Dynamic Gate Stress (DGS) test.

7. The apparatus of claim 1, further including a shuttle device used in the conveyance structure, where the shuttle device comprises:
a die carrier configured to host the array of semiconductor dice under test;
a lid having an array of contact tips configured to contact dice in the die carrier, apply respective individual electrical stimulation signals to said dice in the die carrier and collect therefrom respective individual reaction signals in response to said respective individual electrical stimulation signals being applied, wherein the lid is configured to be coupled to said die carrier to form a microchamber between the lid and the die carrier; and
a gas supply pathway towards said micro chamber.

8. The apparatus of claim 7, wherein the shuttle device further comprises, in addition to said lid, at least one further lid, wherein said lid and said at least one further lid provide an assortment of mutually replaceable lids having respective arrays of contact tips configured to contact dice in said die carrier to apply respective individual electrical stimulation signals to said dice in the die carrier and collect therefrom respective individual reaction signals in response to said respective individual electrical stimulation signals being applied, wherein the lids in said assortment of mutually replaceable lids are couplable, alternatively with said die carrier, to contact dice in said die carrier and perform respective tests applying respective individual electrical stimulation signals to said dice in the die carrier and collect therefrom respective individual reaction signals in response to said respective individual electrical stimulation signals being applied.

9. A shuttle device, comprising:
a die carrier configured to host an array of semiconductor dice under test;
a lid having an array of contact tips configured to contact dice in the die carrier, apply respective individual electrical stimulation signals to said dice in the die carrier and collect therefrom respective individual reaction signals in response to said respective individual electrical stimulation signals being applied, wherein the lid is configured to be coupled to said die carrier to form a microchamber between the lid and the die carrier; and
a gas supply pathway towards said micro chamber.

10. The shuttle device of claim 9, comprising, in addition to said lid, at least one further lid, wherein said lid and said at least one further lid provide an assortment of mutually replaceable lids having respective arrays of contact tips configured to contact dice in said die carrier to apply respective individual electrical stimulation signals to said dice in the die carrier and collect therefrom respective individual reaction signals in response to said respective individual electrical stimulation signals being applied, wherein the lids in said assortment of mutually replaceable lids are couplable, alternatively with said die carrier, to contact dice in said die carrier and perform respective tests applying respective individual electrical stimulation signals to said dice in the die carrier and collect therefrom respective individual reaction signals in response to said respective individual electrical stimulation signals being applied.

11. A method of testing arrays of semiconductor dice under test, the method comprising:
supplying arrays of semiconductor dice under test to a loading station in a testing apparatus;
advancing via a conveyance structure in said testing apparatus said arrays of semiconductor dice under test in a test path through a plurality of test stations in said testing apparatus, wherein each test station in the plurality of test stations identifies as defective individual semiconductor dice under test in said arrays of semiconductor dice under test that fail to pass said at least one respective test; and
directing to a reject destination the individual semiconductor dice under test in said array of semiconductor dice under test identified as defective.

12. The method of claim 11, further comprising producing said arrays of individual semiconductor dice under test by sawing semiconductor dice wafers.

13. The method of claim 11, wherein said arrays of individual semiconductor dice under test comprise unpackaged semiconductor dice.

14. The method of claim 11, further comprising: advancing said arrays of semiconductor dice under test in said test path through said plurality of test stations in said testing apparatus with said arrays of semiconductor dice under test.

15. The method of claim 14, wherein, during said advancing, the arrays of semiconductor dice under test are arranged in a shuttle device, said shuttle device comprising:
a die carrier configured to host the array of semiconductor dice under test;
a lid having an array of contact tips configured to contact dice in the die carrier, apply respective individual electrical stimulation signals to said dice in the die carrier and collect therefrom respective individual reaction signals in response to said respective individual electrical stimulation signals being applied, wherein the lid is configured to be coupled to said die carrier to form a microchamber between the lid and the die carrier; and
a gas supply pathway towards said micro chamber.

16. The method of claim 15, wherein the shuttle device further comprises, in addition to said lid, at least one further lid, wherein said lid and said at least one further lid provide an assortment of mutually replaceable lids having respective arrays of contact tips configured to contact dice in said die carrier to apply respective individual electrical stimulation signals to said dice in the die carrier and collect therefrom respective individual reaction signals in response to said respective individual electrical stimulation signals being applied, wherein the lids in said assortment of mutually replaceable lids are couplable, alternatively with said die carrier, to contact dice in said die carrier and perform respective tests applying respective individual electrical stimulation signals to said dice in the die carrier and collect therefrom respective individual reaction signals in response to said respective individual electrical stimulation signals being applied.

17. The method of claim 16, wherein, during said advancing, said die carrier of the shuttle device is coupled, in respective test stations of said plurality of test stations, with different lids in said assortment of mutually replaceable lids.
